(19) United States
(12) Patent Application Publication
(10) Pub. No.: US 2016/0351675 A1
(43) Pub. Date: Dec. 1, 2016

(54) INTEGRATED CIRCUITS AND METHODS FOR FABRICATING INTEGRATED CIRCUITS HAVING REPLACEMENT METAL GATE ELECTRODES

(71) Applicant: GLOBALFOUNDRIES, Inc., Grand Cayman (KY)

(72) Inventors: Suraj K. Patil, Ballston Lake, NY (US); Mitsuhiro Togo, Burnt Hills, NY (US)

(21) Appl. No.: 14/721,822

(22) Filed: May 26, 2015

(51) Int. Cl. H01L 29/423; H01L 29/49; H01L 27/092; H01L 29/66; H01L 21/8238; H01L 21/225

(52) U.S. Cl. CPC H01L 29/42372; H01L 21/823842; H01L 21/225; H01L 27/0922; H01L 29/66545; H01L 29/4966

(57) ABSTRACT

Integrated circuits and methods for fabricating integrated circuits are provided. In an exemplary embodiment, a method for fabricating integrated circuits includes defining a pFET region and an nFET region of a semiconductor substrate. The method deposits a first work function material including tungsten and nitride over the pFET region and the nFET region of the semiconductor substrate. The method includes selectively modifying the first work function material in a selected region. Further, the method includes depositing a metal fill over the first work function material in the pFET region and the nFET region of the semiconductor substrate.

### TECHNICAL FIELD

The present disclosure generally relates to integrated circuits and methods for fabricating integrated circuits, and more particularly, relates to integrated circuits having replacement metal gate electrodes and methods for fabricating such integrated circuits.

### BACKGROUND

As the critical dimensions of integrated circuits continue to shrink, the fabrication of gate electrodes for complementary metal-oxide-semiconductor (CMOS) transistors has advanced to replace silicon dioxide and polysilicon with high-k dielectric material and metal. A replacement metal gate process is often used to form the gate electrode. A typical replacement metal gate process begins by forming a sacrificial gate oxide material and a sacrificial gate between a pair of spacers on a semiconductor substrate. After further processing steps, such as an annealing process, the sacrificial gate oxide material and sacrificial gate are removed and the resulting trench is filled with a high-k dielectric and one or more replacement metal layers. The replacement metal layers can include work function metals as well as fill metals.

Processes such as atomic layer deposition (ALD), chemical vapor deposition (CVD), physical vapor deposition (PVD), electroplating (EP), and electroless plating (EL) may be used to form the one or more replacement metal layers that form the replacement metal gate electrode. Unfortunately, as critical dimensions decrease, issues such as trench overhang and void formation become more prevalent and pose a greater challenge to overcome. This is due to the smaller gate dimensions. Specifically, at smaller dimensions, the aspect ratio of the trench used to form the replacement metal gate electrode becomes higher as the replacement metal layers form on the trench sidewalls. Metallization of high aspect ratio trenches quite often results in void formation.

Additional issues arise with lateral scaling. For example, lateral scaling presents issues for the formation of contacts. When the contacted gate pitch is reduced to about 64 nanometers (nm), contacts cannot be formed between the gate lines while maintaining reliable electrical isolation properties between the gate line and the contact. Self-aligned contact (SAC) methodology has been developed to address this problem. Conventional SAC approaches involve recessing the replacement metal gate electrode, which includes depositing both work function metal liners, e.g., titanium nitride (TiN), tantalum nitride (TaN), titanium carbide (TiC), tantalum carbide (TaC), or titanium aluminum nitride (TiAlN), and a fill or electrode conductor metal, e.g., aluminum (Al), tungsten (W), copper (Cu) or the like, followed by a dielectric cap material deposition and chemical mechanical planarization (CMP). To set the correct work function for the device, thick work function metal liners may be required, e.g., a combination of different metals such as titanium nitride, tantalum nitride, titanium carbide, tantalum carbide, and titanium aluminum nitride with a total thickness of more than 7 nm. As gate length continues to scale down, for example for sub-15 nm gates, the replacement metal gate electrode structure is so narrow that it will be “pinched-off” by the work function metal liners, leaving little or no space remaining for the lower-resistance fill metal. This causes high resistance issues for devices with small gate lengths, and also causes problems in the SAC replacement metal gate recess process.

Also, conventional replacement metal gate electrodes may suffer from significant threshold voltage variations due to variation in the thicknesses of the work function metal liners. Further, the diffusion of aluminum or fluorine (used in tungsten deposition processes) into the work function metal liners and into the high-k dielectric can alter the threshold voltage of the replacement metal gate electrodes. Conventional processing of titanium nitride involves plasma treatment that can vary threshold voltage of the replacement metal gate electrodes. In addition, conventional replacement metal gate processes may include the deposition of a p-type field effect transistor (“pFET”) appropriate work function metal on an n-type field effect transistor (“nFET”) region and the subsequent removal of the pFET appropriate work function metal from the nFET region. The removal steps often cause non-uniformity issues and surface modification in the nFET region, resulting in threshold voltage variation of the replacement metal gate electrodes.

Accordingly, it is desirable to provide improved integrated circuits having replacement metal gate electrodes and methods for fabricating such improved integrated circuits, particularly as aspect ratios of the replacement metal gate electrodes continue to scale down. Also, it is desirable to provide integrated circuits with replacement metal gate electrodes that exhibit low gate stack resistance and methods for fabricating such integrated circuits. Further, it is desirable to provide integrated circuits with replacement metal gate electrodes that exhibit reduced threshold voltage variation and methods for fabricating such integrated circuits. Also, it is desirable to provide integrated circuits with replacement metal gate electrodes that utilize tungsten-containing work function metals and methods for fabricating such integrated circuits. Furthermore, other desirable features and characteristics will become apparent from the subsequent detailed description and the appended claims, taken in conjunction with the accompanying drawings and the foregoing technical field and background.

### BRIEF SUMMARY

Integrated circuits and methods for fabricating integrated circuits are provided. In one embodiment, a method for fabricating integrated circuits includes providing a semiconductor substrate including a pFET region and an nFET region. The method deposits a first work function material including tungsten and nitride over the pFET region and the nFET region of the semiconductor substrate to form a first work function layer. The method includes selectively modifying the first work function layer in a selected region. Further, the method includes depositing a metal fill over the first work function layer in the pFET region and the nFET region of the semiconductor substrate.

In another embodiment, a method for fabricating an integrated circuit includes providing a semiconductor substrate including a FET region. The method forms a high-k dielectric layer over the FET region of the semiconductor substrate. The method includes forming a tungsten-containing barrier layer over the high-k dielectric layer. The method also deposits a tungsten-containing work function material over the tungsten-containing barrier layer to form a first work function layer. The method further deposits a second work function material different from the tungsten-containing work function material over the tungsten-containing work function material to form a second work function layer. The method includes depositing a gate electrode material over the second work function material.

In another embodiment, an integrated circuit is provided. The integrated circuit includes a first region and a second region of a semiconductor substrate. A first work function layer including tungsten and nitride is located overlying the first region and the second region. The first work function layer is modified in the first region and non-modified in the second region. The integrated circuit includes a second work function layer overlying the first work function layer in the first region and in the second region. Further, the integrated circuit includes a metal fill overlying the second work function layer in the first region and in the second region.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

Embodiments of integrated circuits and methods for fabricating integrated circuits having replacement metal gate electrodes will hereinafter be described in conjunction with the following drawing figures, wherein like numerals denote like elements, and wherein:

FIGS. 1-14 illustrate, in cross section, a portion of a partially fabricated integrated circuit and a method for fabricating an integrated circuit in accordance with various embodiments as described herein.

### DETAILED DESCRIPTION

The following detailed description is merely exemplary in nature and is not intended to limit the integrated circuits or the methods for fabricating integrated circuits claimed herein. Furthermore, there is no intention to be bound by any expressed or implied theory presented in the preceding technical field, background or brief summary, or in the following detailed description.

Integrated circuits having replacement metal gate electrodes and methods for fabricating such integrated circuits are provided that avoid issues faced by conventional processes for forming replacement metal gate electrodes. For example, the methods contemplated herein provide for the formation of integrated circuits with replacement metal gate electrodes exhibiting less threshold voltage variation within an integrated circuit and between integrated circuits. Also, the methods contemplated herein provide for the formation of integrated circuits with replacement metal gate electrodes exhibiting lower overall resistance than conventionally formed replacement metal gate electrodes. For example, the methods contemplated herein utilize a common layer across both nFET regions and pFET regions and chemically modify the layer in one of the regions to provide the appropriate work function. Specifically, the work function of the layer is modified by doping the layer.

A “work function” is generally described as the energy, usually measured in electron volts, needed to remove an electron from the Fermi level to a point immediately outside the solid surface or the energy needed to move an electron from the Fermi level into vacuum. Work function is a material property of any material, whether the material is a conductor, semiconductor, or dielectric. For a metal, the Fermi level lies within the conduction band, indicating that the band is partly filled. For an insulator, the Fermi level lies within the band gap, indicating an empty conduction band. For insulators, the minimum energy to remove an electron is about the sum of half the band gap and the electron affinity. An effective work function is defined as the work function of metal on the dielectric side of a metal-dielectric interface.

The work function of a semiconductor material can be altered by doping the semiconductor material. For example, undoped polysilicon has a work function of about 4.65 eV, whereas an exemplary polysilicon doped with boron has a work function of about 5.15 eV. When a semiconductor or conductor is used in a gate electrode, the work function of the semiconductor or conductor directly affects the threshold voltage of the transistor.

The work function of the semiconductor or conductor used in gate electrodes is a parameter for setting the threshold voltage of a field effect transistor (FET), whether an nFET or pFET. In order to obtain a target electrical control of the FET devices, the work function value of the semiconductor or conductor used in gate electrodes should be close to the valence band of the semiconductor or conductor for a pFET and close to the conduction band of the semiconductor or conductor for an nFET, and more particularly, 5.2 eV and 4.0 eV, respectively for the pFET and nFET in the case of silicon.

Embodiments described herein provide for the use of a work function layer in gate electrodes that is formed over both an nFET region and a pFET region. A “work function layer” is provided for modulating the work function of a gate electrode that includes the work function layer. As deposited, the work function layer is appropriate for use in either the nFET region or the pFET region. In the other region, the work function layer is chemically modified, rather than removed, so that it is appropriate for use in that region.

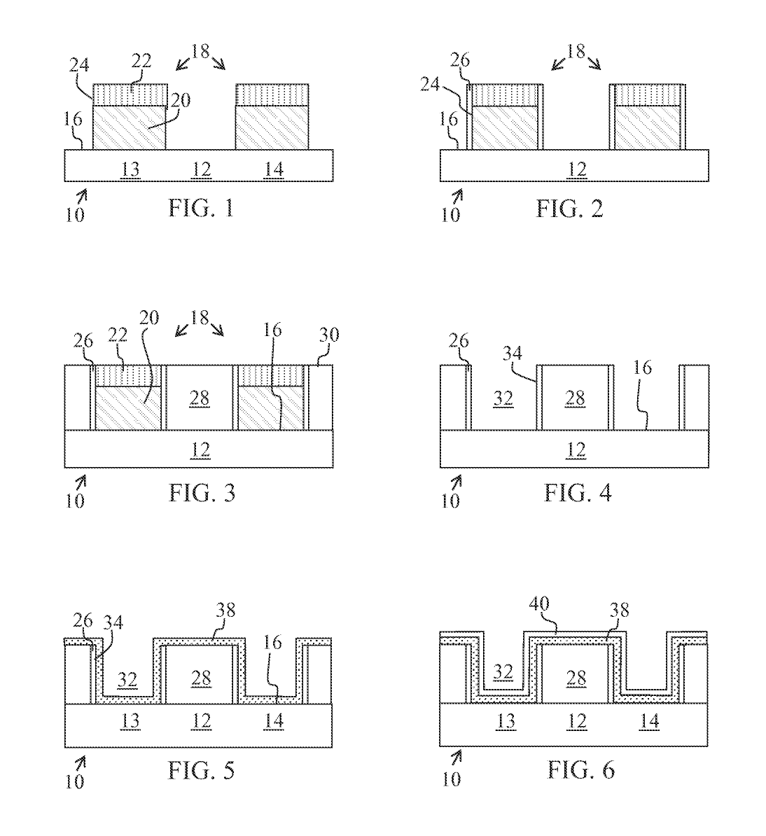

FIGS. 1-14 illustrate partially fabricated integrated circuits in accordance with various embodiments of methods for fabricating integrated circuits. Various processes in the design and composition of integrated circuits are well known and so, in the interest of brevity, many conventional processes will only be mentioned briefly herein or will be omitted entirely without providing the well-known process details. Further, it is noted that integrated circuits include a varying number of components and that single components shown in the illustrations may be representative of multiple components.

In FIG. 1, a partially fabricated integrated circuit 10 is shown and includes a semiconductor substrate 12. It is to be appreciated that various fabrication techniques may be conducted in accordance with the methods described herein to form the partially fabricated integrated circuit 10 as shown. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The semiconductor substrate 12 may include a compound semiconductor such as silicon carbide, silicon germanide, gallium arsenide, indium arsenide, indium gallium arsenide, indium gallium arsenide phosphide, or indium phosphide and combinations thereof. In an exemplary embodiment, the semiconductor material is a silicon substrate. The silicon substrate may be a bulk silicon wafer or may be a thin layer of silicon (on an insulating layer commonly known as silicon-on-insulator or SOI) that, in turn, is supported by a carrier wafer. As referred to herein, a material that includes a recited element/compound includes the recited element/compound in an amount of at least 10 weight percent based on the total weight of the material unless otherwise indicated. Also, the semiconductor substrate 12 may be planar or in the form of fin structures for use in a FinFET.

The semiconductor substrate 12 is provided with a first region 13 and second region 14 for later processing. For example, the first region 13 may be one of an nFET region or a pFET region and the second region 14 may be the other of the nFET region or the pFET region. As described below, integrated circuit fabrication processes may differ for the regions 13 and 14 to form the appropriate replacement metal gate electrodes for the pFET region or the nFET region. The first region 13 and second region 14 may be formed by impurity doping. For example, an nFET region may be formed with a P-type well region by doping the semiconductor substrate 12 with boron ions. A pFET region may be formed with an N-type well region by doping the semiconductor substrate 12 with phosphorus or arsenic ions.

As shown in FIG. 1, the semiconductor substrate is provided with a substantially planar surface 16. Sacrificial gate structures 18 are formed overlying the surface 16. As referred to herein, the term “overlying” is used to encompass both “over” and “on”, with features that “overlie” other features being disposed over and possibly directly upon the underlying features. In this regard, the sacrificial gate structures 18 may lie directly on the semiconductor substrate 12 such that they make physical contact with the semiconductor substrate 12 or they may lie over the semiconductor substrate 12 such that another material layer is interposed between the semiconductor substrate 12 and the sacrificial gate structures 18. Each exemplary sacrificial gate structure 18 includes a sacrificial gate 20 and a sacrificial cap 22 overlying the sacrificial gate 20. The sacrificial gate structures 18 can be fabricated using conventional processing techniques such as material deposition, photolithography, and etching. In this regard, fabrication of the sacrificial gate structures 18 may begin by forming at least one layer of sacrificial gate material overlying the surface 16. For this example, the material used for the sacrificial gates 20 is formed overlying the surface 16, and then a hard mask material used for the sacrificial caps 22 is formed overlying the sacrificial gate material. The sacrificial gate material typically includes a polycrystalline silicon material, and the hard mask material typically includes a silicon nitride material or a silicon oxide material. In typical embodiments, the sacrificial gate materials are blanket deposited on the surface 16 in a conformal manner (using, for example, chemical vapor deposition (CVD), physical vapor deposition (PVD) or another suitable deposition technique).

The hard mask layer is photolithographically patterned to form a sacrificial gate etch mask, and the underlying sacrificial gate material is anisotropically etched into the desired topology that is defined by the sacrificial gate etch mask. The resulting sacrificial gate structures 18 including sacrificial gates 20 and sacrificial caps 22 are depicted in FIG. 1, and have sides 24.

After the sacrificial gate structures 18 have been created, the process may continue by forming spacers 26 adjacent the sides 24 of the sacrificial gate structures 18. In this regard, FIG. 2 depicts the state of the partially fabricated integrated circuit 10 after the formation of the spacers 26. The spacers 26 are formed adjacent to and on the sides 24 of the sacrificial gate structures 18. Formation of the spacers 26 includes conformally depositing a spacer material overlying the sacrificial gate structures 18 and the surface 16 to form a spacer layer (not shown). The spacer layer includes an appropriate insulator, such as silicon nitride. The spacer material can be deposited in a known manner by, for example, atomic layer deposition (ALD), CVD, low pressure chemical vapor deposition (LPCVD), semi-atmospheric chemical vapor deposition (SACVD), or plasma enhanced chemical vapor deposition (PECVD). The spacer material is deposited to a thickness so that, after anisotropic etching, the spacers 26 have a thickness that is appropriate for the subsequent etching steps described below. Thereafter, the spacer layer is anisotropically and selectively etched to define the spacers 26. In practice, the spacer layer can be etched by, for example, reactive ion etching (RIE) using a suitable etching chemistry.

After the spacers 26 have been created, other processing may be performed to form desired source/drain regions in the semiconductor substrate 18, such as trench etching in the substrate 12 and epitaxial deposition of source/drain material, stressing techniques, and ion implantations using the sacrificial gate structures 18 as ion implantation masks. The manufacturing process may proceed by forming regions of dielectric material 28 surrounding the spacers 26. FIG. 3 depicts the state of the partially fabricated integrated circuit 10 after the regions of dielectric material 28 have been formed. At this point in the fabrication process, previously unoccupied space around the spacers 26 has been completely filled with the dielectric material, such as by blanket deposition.

In certain embodiments, the regions of dielectric material 28 are formed from an interlayer dielectric (ILD) material that is initially blanket deposited overlying the surface 16 of the substrate 12, the sacrificial gate structures 18, and the spacers 26 using a well-known material deposition technique such as CVD, LPCVD, or PECVD. The dielectric material is deposited such that it fills the spaces adjacent to the spacers 26 and such that it covers the spacers 26 and the sacrificial caps 22. Thereafter, the deposited dielectric material 28 is planarized using, for example, a chemical mechanical polishing tool and such that the sacrificial caps 22 serve as a polish stop indicator to produce an exposed surface 30 of the regions of dielectric material 28

The exemplary fabrication process proceeds in FIG. 4 by removing the sacrificial gate structures 18 while leaving the spacers 26 intact or at least substantially intact. FIG. 4 depicts the state of the partially fabricated integrated circuit 10 after removal of the sacrificial gate structures 18. Removal of the sacrificial gate structures 18 results in the removal of the sacrificial caps 22 and the removal of the sacrificial gates 20. Accordingly, removal of the sacrificial gate structures 18 exposes the surface 16 of the semiconductor substrate 12 between the spacers 26. Removal of the sacrificial gate structures 18 results in the formation of trenches 32 in the regions of dielectric material 28. As shown, the trenches 32 are bounded by trench surfaces 34 formed by the spacers 26 and the surface 16 of the semiconductor substrate 12.

In certain embodiments, the sacrificial gate structures 18 are removed by sequentially or concurrently etching the sacrificial caps 22 and the sacrificial gates 20 in a selective manner, stopping at the desired point. The etching chemistry and technology used for this etching technique is chosen such that the spacers 26 and the dielectric material 28 are not etched (or only etched by an insignificant amount). Etching of the sacrificial gates 20 may be controlled to stop at the top of the semiconductor substrate 12. The sacrificial gate structures 18 are removed by dry etching, wet etching, or a combination of dry and wet etching.

FIGS. 5-14 illustrate further processing of the partially fabricated integrated circuit 10 of FIG. 4 to form replacement metal gate electrodes 80. The materials and techniques used in the processing of FIGS. 5-14 may differ depending on the type of region the first region 13 and second region 14 are. For example, the first region 13 may be an nFET region where an nFET type replacement metal gate electrode will be formed over a p-type well, and the second region 14 may be a pFET region where a pFET type replacement metal gate electrode will be formed over an n-type well. Alternatively, the first region 13 may be a pFET region where a pFET type replacement metal gate electrode will be formed over an n-type well, and the second region 14 may be an nFET region where an nFET type replacement metal gate electrode will be formed over a p-type well. Each embodiment will be discussed herein. First described is the embodiment in which the first region 13 is an nFET region and the second region 14 is a pFET region.

As shown in FIG. 5, a high-k dielectric layer 38 is conformally deposited over the partially fabricated integrated circuit 10. As used herein, “high k” denotes a dielectric material featuring a dielectric constant (k) higher than about 3.9. The high-k dielectric layer 38 is formed over regions 13 and 14 of the semiconductor substrate 12, including along the spacers 26 in the trenches 32, and over the dielectric material 28 outside of the trenches 32. An exemplary high-k dielectric layer 38 is formed from hafnium oxide (HfO₂), hafnium silicate (HfSiOₓ), hafnium oxide silicate nitride (HfOₓSi_{y}N_{z}), zirconium oxide (ZrO₂) or lanthanum oxide (La₂O₃), although other high-k dielectric materials are also contemplated. In an exemplary embodiment, the high-k dielectric layer 38 is formed by ALD. The high-k dielectric layer 38 may have a thickness of about 14 Å to about 18 Å, such as about 15 Å.

After formation of the high-k dielectric layer 38, the exemplary method continues in FIG. 6 with formation of a barrier layer 40. The exemplary barrier layer 40 is conformally formed over the high-k dielectric layer 38, both within and outside of the trenches 32. An exemplary barrier layer 40 is formed from tungsten carbide or titanium nitride, though other suitable materials may be used. An exemplary process for forming the barrier layer 40 is ALD. An exemplary tungsten carbide barrier layer 40 may be formed with a thickness of about 8 Å to about 15 Å, such as about 10 Å. An exemplary titanium nitride barrier layer 40 may be formed with a thickness of about 15 Å to about 25 Å, such as about 20 Å. FIG. 6 illustrates the structure of the partially fabricated integrated circuit 10 after formation of the barrier layer 40.

The exemplary fabrication process proceeds by forming a work function metal layer or stack of work function metal layers to provide the replacement metal gate electrodes having desired electrical characteristics. In FIG. 7, a first work function layer 42 is formed overlying the barrier layer 40. The work function layer 42 may include a single work function metal, or a stack of work function metals. An exemplary work function layer 42 contains tungsten. When the first region 13 is an nFET region, an exemplary work function layer 42 is tungsten nitride. Another exemplary work function layer 42 is tungsten carbide. The work function of tungsten nitride may range from about 3.5 eV to about 4.3 eV and increases with increased nitrogen content. Tungsten and nitrogen content can be controlled through the deposition process conditions as is well known. For tungsten carbide, work function decreases with increased carbon content. The exemplary work function layer 42 is conformally formed over the barrier layer 40. In an exemplary embodiment, the work function layer 42 is formed by ALD. An exemplary work function layer 42 is formed with a thickness of from about 10 Å to about 20 Å, such as about 15 Å. As shown, the work function layer 42 is formed over both regions 13 and 14 of the semiconductor substrate 12.

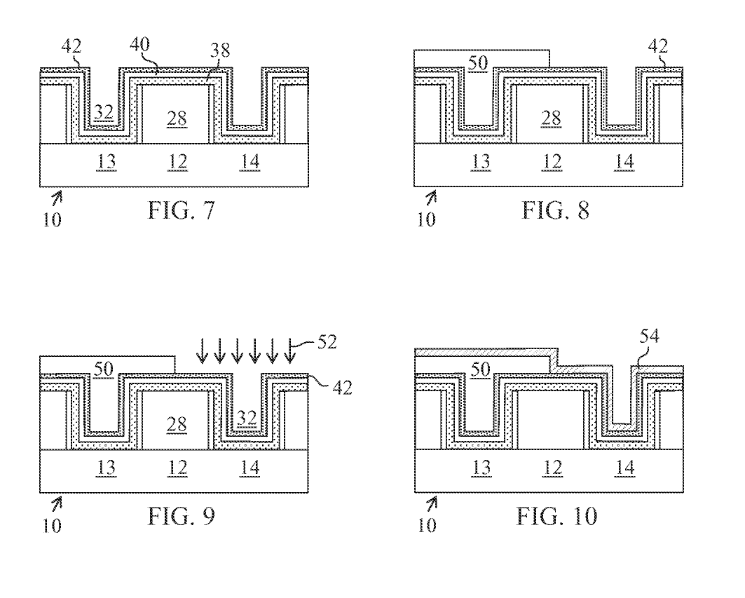

In FIG. 8, a mask 50 is formed and patterned to cover the first region 13 and expose the second region 14. For example, photoresist may be deposited and processed conventionally to form the mask 50. The mask 50 covers the work function layer 42 in the first region 13 while the work function layer 42 in the second region 14 remains exposed so that the work function layer 42 in the second region 14 may be chemically modified for use in the pFET replacement metal gate electrode to be formed there.

FIGS. 9 and 10 provide alternative exemplary methods for chemically modifying the work function layer 42 overlying the second region 14. Specifically, the work function layer 42 overlying the second region 14 is doped with an ion type to change its work function value. In FIG. 9, an implantation process is performed to implant ions 52 into the exposed portion of the work function layer 42 overlying the second region 14. As shown, the ions 52 are implanted into the exposed portion of the work function layer 42 overlying the second region 14 while the mask 50 prevents implantation into the work function layer 42 overlying the first region 13. In an exemplary process, silicon ions or nickel ions are implanted into the work function layer 42. Doping with such ions alters the work function value of the work function layer 42 overlying the second region 14 to be appropriate for use in the pFET replacement metal gate electrodes. For example, the silicon doped tungsten nitride may have a work function value higher than the work function value of tungsten nitride. The implantation may be performed with silicon ions at an energy between about 2 KeV to about 20 KeV, and at a dose between about 1E14 to about 1E18 atoms/cm². After implantation, the mask 50 may be removed.

In other embodiments, the work function layer 42 overlying the second region 14 may be modified by alternative techniques as shown in FIG. 10. In FIG. 10, a capping layer 54 is formed over the mask 50 and the exposed portion of the work function layer 42 overlying the second region 14. For the embodiment in which the second region 14 is a pFET region, an exemplary capping layer 54 is amorphous silicon. In an exemplary embodiment, the capping layer 54 is deposited by CVD. An exemplary capping layer 54 is formed with a thickness of from about 8 Å to about 15 Å, such as about 10 Å. After forming the capping layer 54, an annealing process is performed. For example, the annealing process may include heating the partially fabricated integrated circuit to a temperature of from about 700° C. to about 1050° C., such as about 900° C., for a duration of about 0.1 milliseconds to about 10 seconds. An exemplary anneal process may be a flash anneal, spike anneal or laser based anneal. The annealing process causes diffusion of silicon ions from the amorphous silicon capping layer 54 into the exposed portion of the work function layer 42 overlying the second region 14. As a result, the work function layer 42 overlying the second region 14 is silicon doped. An exemplary work function layer overlying the second region 14 is silicon doped tungsten nitride. After the anneal process, the capping layer 54 and the mask 50 may be removed from the partially fabricated integrated circuit 10.

As a result of the modification or doping process of either FIG. 9 or FIG. 10, the partially fabricated integrated circuit 10 has the structure shown in FIG. 11. Specifically, the work function layer 42 is located over both the first region 13 and the second region 14. However, the work function layer 42 remains in an unmodified state by the process of FIG. 9 or 10 in the portion 60 overlying the first region 13 and is in a modified state by the process of FIG. 9 or 10 overlying the second region 14. Specifically, the exemplary unmodified work function layer 42 in portion 60 is tungsten nitride and the exemplary modified work function layer 42 in portion 62 is silicon-doped tungsten nitride.

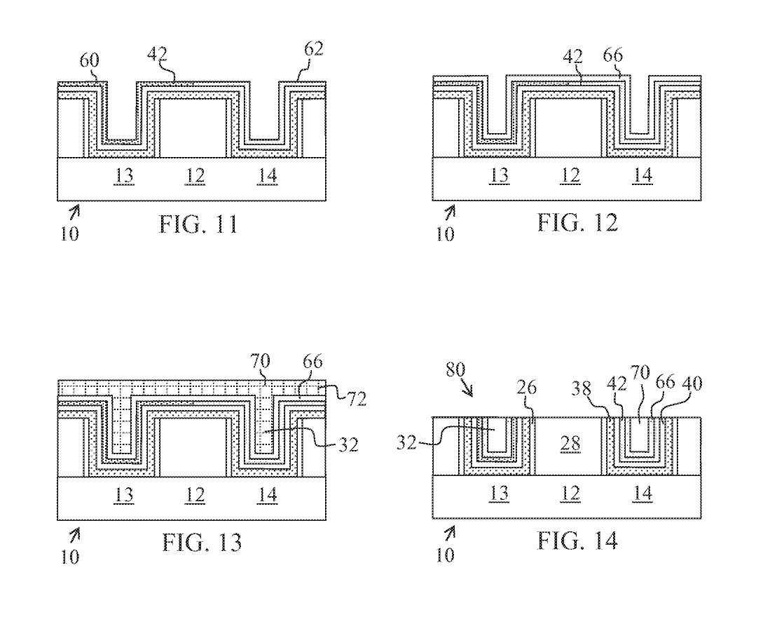

The exemplary fabrication process proceeds in FIG. 12 by forming a second work function metal layer 66 or stack of second work function metal layers to provide the gate structures to be formed with desired electrical characteristics. The second work function layer 66 is formed overlying the first work function layer 42. An exemplary second work function layer 66 includes tungsten. For example, the second work function layer 66 may be tungsten carbide. Alternatively, the second work function layer 66 may be titanium nitride or another work function modulating material. As shown, the work function layer 66 is formed over both regions 13 and 14 of the semiconductor substrate 12. The exemplary second work function layer 66 is conformally formed over the first work function layer 42. In an exemplary embodiment, the second work function layer 66 is formed by ALD. An exemplary second work function layer 66, such as a tungsten carbide work function layer, is formed with a thickness of from about 8 Å to about 15 Å, such as about 10 Å. In another exemplary embodiment, the second work function layer 66, such as a titanium nitride work function layer, is formed with a thickness of from about 15 Å to about 30 Å, such as about 20 Å.

In FIG. 13, a metal fill is deposited to form a metal layer 70 over the work function layer 66 over the first region 13 and second region 14. As shown, the metal layer 70 fills the trenches 32 over the first region 13 and second region 14. An overburden portion 72 of the metal layer 70 is formed outside of the trenches 32 and overlying an upper surface of the second work function layer 66.

An exemplary metal fill is a gate metal, such as tungsten, aluminum, cobalt, or copper, with the metal fill including a majority of one or more of the aforementioned gate metals based upon the total weight of the metal fill. Another exemplary metal fill is low resistance tungsten. Such tungsten may be deposited by a CVD process. In other embodiments, the metal fill may be deposited by ALD, a nitrogen assisted CVD process, or another conformal process. In an exemplary embodiment, the trenches 32 have a width of from about 120 Å to about 180 Å, such as about 140 Å. Thus, filling the trenches 32 requires that the metal layer 70 have a thickness of at least from about 60 Å to about 90 Å. An exemplary metal layer 70 has a thickness of from about 60 Å to about 1000 Å.

In FIG. 14, a planarization process, such as chemical mechanical planarization (CMP) is performed to remove the portions of the high-k dielectric layer 38, barrier layer 40, first work function layer 42, second work function layer 66, and metal layer 70 located outside of the trenches 32 and over the dielectric material 28. The planarization process may remove a portion of the spacers 26 and the dielectric material 28. As a result of the planarization process, a replacement metal gate electrode 80 is formed over each region 13 and 14.

In exemplary embodiments herein, the barrier layer 40, work function layer 42, work function layer 66 and metal fill 70 each include tungsten. For example, barrier layer 40 may be tungsten carbide, work function layer 42 may be tungsten nitride and silicon doped tungsten nitride or tungsten carbide nitride and aluminum doped tungsten carbide nitride, work function layer 66 may be tungsten carbide, and metal fill 70 may be tungsten. The materials used for the barrier and/or work function layers act as diffusion barriers against aluminum and fluorine diffusion.

Referring back to FIG. 5, the embodiment in which the first region 13 is a pFET region and the second region 14 is an nFET region will now be described. As shown in FIG. 5, a high-k dielectric layer 38 is conformally deposited over the partially fabricated integrated circuit 10. Specifically, the high-k dielectric layer 38 is formed over regions 13 and 14 of the semiconductor substrate 12, including along the spacers 26 in the trenches 32, and over the dielectric material 28 outside of the trenches 32. An exemplary high-k dielectric layer 38 is formed from hafnium oxide (HfO₂), hafnium silicate (HfSiOₓ), hafnium oxide silicate nitride (HfOₓSi_{y}N_{z}), zirconium oxide (ZrO₂) or lanthanum oxide (La₂O₃), although other high-k dielectric materials are also contemplated. In an exemplary embodiment, the high-k dielectric layer 38 is conformally deposited by ALD. The high-k dielectric layer 38 may have a thickness of about 14 Å to about 18 Å, such as about 15 Å.

After formation of the high-k dielectric layer 38, the exemplary method continues in FIG. 6 with formation of a barrier layer 40. The exemplary barrier layer 40 is conformally deposited over the high-k dielectric layer 38, both within and outside of the trenches 32. An exemplary barrier layer 40 is tungsten carbide or titanium nitride, though other suitable materials may be used. An exemplary process for depositing the barrier layer 40 is ALD. An exemplary tungsten carbide barrier layer 40 may be formed with a thickness of about 8 Å to about 15 Å, such as about 10 Å. An exemplary titanium nitride barrier layer 40 may be formed with a thickness of about 15 Å to about 25 Å, such as about 20 Å. FIG. 6 illustrates the structure of the partially fabricated integrated circuit 10 after deposition of the barrier layer 40.

The exemplary fabrication process proceeds by forming a work function metal or stack of work function metals to provide the replacement metal gate electrodes to be formed with desired electrical characteristics. In FIG. 7, a first work function layer 42 is formed overlying the barrier layer 40. The work function layer 42 may include a single work function metal, or a stack of work function metals. An exemplary work function layer 42 contains tungsten. When the first region 13 is a pFET region, an exemplary work function layer 42 is tungsten carbide nitride. The work function of tungsten carbide nitride may range from about 4.1 eV to about 5.1 eV and may be modified by varying the ratio of tungsten, carbon and nitrogen through the deposition process conditions as is well known. The exemplary work function layer 42 is conformally deposited over the barrier layer 40. In an exemplary embodiment, the work function layer 42 is deposited by ALD. An exemplary work function layer 42 is formed with a thickness of from about 10 Å to about 20 Å, such as about 15 Å. As shown, the work function layer 42 is deposited over both regions 13 and 14 of the semiconductor substrate 12.

In FIG. 8, a mask 50 is formed and patterned to cover the first region 13 and expose the second region 14. For example, photoresist may be deposited and processed conventionally to form the mask 50. The mask 50 exposes the work function layer 42 in the second region 14 so that the work function layer 42 in the second region 14 may be modified for use in the nFET replacement metal gate electrode to be formed there.

FIGS. 9 and 10 provide alternative methods for modifying the work function layer 42 overlying the second region 14. Specifically, the work function layer 42 overlying the second region 14 is doped with an ion type to change its work function value. In FIG. 9, an implantation process is performed to implant ions 52 into the exposed portion of the work function layer 42 overlying the second region 14. As shown, the ions 52 are implanted into the exposed portion of the work function layer 42 overlying the second region 14 while the mask 50 prevents implantation into the work function layer 42 overlying the first region 13. In an exemplary process, aluminum ions or lanthanum ions are implanted into the work function layer 42. Doping with such ions alters the work function value of the work function layer 42 overlying the second region 14 to be appropriate for use in the nFET replacement metal gate electrodes. For example, aluminum doped tungsten carbide nitride may have a work function value lower than the work function value of tungsten carbide nitride. The implantation may be performed with aluminum ions at an energy between about 1 KeV to about 20 KeV, and at a dose between about 1E14 to about 1E18 atoms/cm². After implantation, the mask 50 may be removed.

The work function layer 42 overlying the second region 14 may modified by alternative means as shown in FIG. 10. In FIG. 10, a capping layer 54 is formed over the mask 50 and the exposed portion of the work function layer 42 overlying the second region 14. For the embodiment in which the second region 14 is an nFET region, an exemplary capping layer 54 is aluminum or an aluminum-containing material. In an exemplary embodiment, the capping layer 54 is deposited by ALD. An exemplary capping layer 54 is formed with a thickness of from about 8 Å to about 15 Å, such as about 10 Å. After depositing the capping layer 54, an annealing process is performed. For example, the annealing process may include heating the partially fabricated integrated circuit to a temperature of from about 400° C. to about 1050° C., such as about 500° C., for a duration of about 0.5 milliseconds to about 10 seconds. An exemplary anneal process may be a rapid thermal anneal (RTA), flash anneal, spike anneal or laser based anneal. The annealing process causes diffusion of aluminum ions from the aluminum capping layer 54 into the exposed portion of the work function layer 42 overlying the second region 14. As a result, the work function layer 42 overlying the second region 14 is aluminum doped. An exemplary work function layer overlying the second region 14 is aluminum doped tungsten carbide nitride. After the anneal process, the capping layer 54 and the mask 50 may be removed from the partially fabricated integrated circuit 10.

As a result of the modification or doping process of either FIG. 9 or FIG. 10, the partially fabricated integrated circuit 10 has the structure shown in FIG. 11. Specifically, the work function layer 42 is located over both the first region 13 and the second region 14. However, the work function layer 42 remains in an unmodified or undoped state in the portion 60 overlying the first region 13 and is in a modified or doped state overlying the second region 14. Specifically, the exemplary unmodified work function layer 42 in portion 60 is tungsten carbide nitride and the exemplary modified work function layer 42 in portion 62 is aluminum doped tungsten carbide nitride.

The exemplary fabrication process proceeds in FIG. 12 by forming a work function metal or stack of work function metals to provide the gate structures to be formed with desired electrical characteristics. The second work function layer 66 is formed overlying the work function layer 42. The work function layer 66 may include a single work function metal, or a stack of work function metals. An exemplary work function layer 66 includes tungsten. For example, the work function layer 66 may be tungsten carbide. Alternatively, the work function layer 66 may be titanium nitride or another work function modulating material. As shown, the work function layer 66 is deposited over both regions 13 and 14 of the semiconductor substrate 12. The exemplary work function layer 66 is conformally deposited over the work function layer 42. In an exemplary embodiment, the work function layer 66 is deposited by ALD. An exemplary work function layer 66, such as a tungsten carbide work function layer, is formed with a thickness of from about 8 Å to about 15 Å, such as about 10 Å. An exemplary work function layer 66, such as a titanium nitride work function layer, is formed with a thickness of from about 15 Å to about 30 Å, such as about 20 Å.

In FIG. 13, a metal fill 70 is deposited over the partially fabricated integrated circuit 10. Specifically, the metal fill 70 is deposited over the work function layer 66 over the first region 13 and second region 14. As shown, the metal fill 70 fills the trenches 32 over the first region 13 and second region 14. An overburden portion 72 of the metal fill 70 is formed outside of the trenches 32 and overlying an upper surface of the work function layer 66.

An exemplary metal fill 70 is a gate metal, such as tungsten, aluminum, cobalt, or copper. An exemplary metal fill 70 is low resistance tungsten such as deposited by a CVD process. In other embodiments, the metal fill 70 may be deposited by ALD, a nitrogen assisted CVD process, or another conformal process. In an exemplary embodiment, the trenches 32 have a width of from about 120 Å to about 180 Å, such as about 140 Å. Thus, filling the trenches 32 requires that the metal fill 70 have a thickness of at least from about 60 Å to about 90 Å. An exemplary metal fill 70 has a thickness of from about 60 Å to about 1000 Å.

In FIG. 14, a planarization process, such as chemical mechanical planarization (CMP) is performed to remove the portions of the high-k dielectric layer 38, barrier layer 40, work function layer 42, work function layer 66, and metal fill 70 located outside of the trenches 32 and over the dielectric material 28. The planarization process may remove a portion of the spacers 26 and the dielectric material 28. As a result of the planarization process, a replacement metal gate electrode 80 is formed over each region 13 and 14.

After formation of the replacement metal gate electrodes 80, further processing may be performed to complete the integrated circuit 10. For example and although not shown, back-end-of-line processing may involve the formation of gate caps, deposition of interlayer dielectric materials, formation of contacts, and formation of interconnects between devices on the semiconductor substrate 12.

In exemplary embodiments herein, the barrier layer 40, work function layer 42, work function layer 66 and metal fill 70 each include tungsten. For example, barrier layer 40 may be tungsten carbide, work function layer 42 may be tungsten nitride and silicon doped tungsten nitride or tungsten carbide nitride and aluminum doped tungsten carbide nitride, work function layer 66 may be tungsten carbide, and metal fill 70 may be tungsten. The materials used for the barrier and/or work function layers act as diffusion barriers against aluminum and fluorine diffusion.

The integrated circuits and methods for fabricating integrated circuits described herein provide for replacement metal gate electrodes having improved threshold voltage uniformity, i.e., reduced threshold voltage variability. Specifically, conventional material deposition processes that increase threshold voltage variability, such as plasma treatment of titanium nitride, are avoided in accordance with the techniques described herein. Further, the methods described herein may exhibit a reduction in deposition processes (i.e., use of fewer layers). Also, the methods described herein avoid the removal of a work function layer from either region, instead modifying the work function layer in one region to allow for its use therein. Further, the materials used for the barrier and/or work function layers may provide for better etch selectivities as compared to conventional processing. The materials used for the barrier and/or work function layers may also be better diffusion barriers against aluminum and fluorine diffusion as compared to conventional processing.

Exemplary embodiments provided herein allow for thinner barrier and work function layers than in conventional processing. As a result, a larger ratio of metal fill may be provided in the replacement metal gate electrodes as compared to replacement metal gate electrode formed in accordance with conventional processing. Further, by reducing the thickness of barrier and work function layers, the trench to be filled by the metal fill is wider and more easily filled, i.e., the processing herein provides for better trench filling capability. In addition, the wider trench may allow for use of ultra low resistance tungsten deposition processes, thereby providing for lower gate resistance.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1. A method for fabricating an integrated circuit, the method comprising:
providing a semiconductor substrate including a pFET region and an nFET region;
depositing a first work function material over the pFET region and the nFET region of the semiconductor substrate to form a first work function layer having a thickness of from about 10 Å to about 20 Å, wherein the first work function material comprises tungsten carbide or tungsten carbide nitride;
selectively modifying the first work function layer over a selected region to define a modified first work function layer having a first work function value over the selected region and a non-modified first work function layer having a second work function value over a non-selected region, wherein the first work function is different from the second work function value; and
depositing a metal fill over the modified first work function layer and over the non-modified first work function layer.

2. The method of claim 1 further comprising:
depositing a high-k dielectric material over the pFET region and the nFET region of the semiconductor substrate to form a high-k dielectric layer;
forming a first metal over the high-k dielectric layer over the pFET region and the nFET region of the semiconductor substrate, wherein depositing the first work function material comprises depositing a second metal onto the first metal; and
depositing a third metal on the second metal over the pFET region and the nFET region of the semiconductor substrate to form a second work function layer.

3. The method of claim 1 wherein depositing the first work function material comprises forming the first work function layer having a thickness of about 15 Å.

4. The method of claim 1 wherein depositing the first work function material comprises depositing a first work function metal by an atomic layer deposition (ALD) process.

5. The method of claim 1 further comprising forming a barrier layer with a thickness from about 8 Å to about 15 Å or from about 15 Å to about 25 Å over the high-k dielectric layer over the pFET region and the nFET region of the semiconductor substrate, wherein depositing the first work function material comprises depositing the first work function material on to the barrier layer.

6. (canceled)

7. The method of claim 1 further comprising depositing by a first atomic layer deposition (ALD) process a first metal with a thickness of from about 8 Å to about 15 Å or from about 15 Å to about 25 Å over the high-k dielectric layer over the pFET region and the nFET region of the semiconductor substrate, wherein depositing the first work function material comprises depositing by a second ALD process a second metal on to the first metal.

8. The method of claim 1 wherein depositing the first work function material comprises forming the first work function material consisting of tungsten carbide.

9. The method of claim 8 further comprising forming a barrier layer over the high-k dielectric layer over the pFET region and the nFET region of the semiconductor substrate, wherein the barrier layer consists essentially of tungsten carbide, and wherein depositing the first work function material comprises depositing the first work function material on to the barrier layer.

10. The method of claim 1 further comprising:
depositing by a first atomic layer deposition (ALD) process a first metal over the pFET region and the nFET region of the semiconductor substrate, wherein depositing the first work function material comprises depositing by a second ALD process a second metal onto the first metal; and
depositing by a third ALD process a third metal on to the second metal over the pFET region and the nFET region of the semiconductor substrate to form a second work function layer.

11. The method of claim 1 further comprising:
depositing by a first atomic layer deposition (ALD) process a first metal over the pFET region and the nFET region of the semiconductor substrate to form a metal barrier layer having a thickness of from about 8 Å to about 15 Å or from about 15 Å to about 25 Å, wherein depositing the first work function material comprises depositing by a second ALD process a second metal onto the first metal; and
depositing by a third ALD process a third metal on to the second metal over the pFET region and the nFET region of the semiconductor substrate to form a second work function layer having a thickness of from about 8 Å to about 15 Å or from about 15 Å to about 30 Å.

12. The method of claim 1 further comprising:
depositing by a first atomic layer deposition (ALD) process a first metal over the pFET region and the nFET region of the semiconductor substrate to form a metal barrier layer having a thickness of about 10 Å, wherein depositing the first work function material comprises depositing by a second ALD process a second metal onto the first metal to form the first work function layer having a thickness of about 15 Å; and
depositing by a third ALD process a third metal on to the second metal over the pFET region and the nFET region of the semiconductor substrate to form a second work function layer having a thickness of about 10 Å.

13. The method of claim 1 further comprising depositing tungsten carbide to form a metal barrier layer over the pFET region and the nFET region of the semiconductor substrate, wherein depositing the first work function material comprises depositing the first work function material on to the metal barrier; and wherein the metal barrier layer is not modified while selectively modifying the first work function layer.

14. (canceled)

15. A method for fabricating an integrated circuit, the method comprising:
providing a semiconductor substrate including a FET region;
forming a high-k dielectric layer over the FET region of the semiconductor substrate;
forming a tungsten-containing barrier layer over the high-k dielectric layer;
depositing a first tungsten-containing work function material on the tungsten-containing barrier layer to form a first tungsten-containing work function layer;
depositing a second tungsten-containing work function material on the first tungsten-containing work function layer, wherein the second tungsten-containing work function material is different from the first tungsten-containing work function material; and
depositing a gate electrode material on the second work function material, wherein all layers intervening between the gate electrode material and the high-k dielectric layer include tungsten.

16. The method of claim 15 further comprising forming a trench having sidewalls and a bottom surface in the FET region of the semiconductor substrate, wherein:
forming a high-k dielectric layer over the FET region of the semiconductor substrate comprises covering the sidewalls and the bottom surface of the trench with the high-k dielectric layer;
forming a tungsten-containing barrier layer over the high-k dielectric layer comprises encapsulating the high-k dielectric layer in the trench;
depositing a first tungsten-containing work function material on the tungsten-containing barrier layer comprises encapsulating the tungsten-containing barrier layer in the trench;
depositing a second tungsten-containing work function material on the first tungsten-containing work function layer comprises encapsulating the first tungsten-containing work function layer in the trench; and
depositing a gate electrode material on the second work function material comprises forming a tungsten-containing gate electrode material on the second tungsten-containing work function material, wherein the trench inside of the high-k dielectric layer is filled only with tungsten-containing material.

17. The method of claim 15 wherein the first tungsten-containing work function layer has an initial thickness and further comprising doping the first tungsten-containing work function layer to form a doped work function layer having a thickness equal to the initial thickness.

18. The method of claim 15 wherein:
forming the tungsten-containing barrier layer over the high-k dielectric layer comprises depositing tungsten carbide over the high-k dielectric layer;
depositing the first tungsten-containing work function material over the tungsten-containing barrier layer comprises depositing tungsten carbide nitride over the tungsten-containing barrier layer; and
depositing the second tungsten-containing work function material on the first tungsten-containing work function layer comprises depositing tungsten carbide on the first tungsten-containing work function layer.

19. The method of claim 15 wherein:
forming the tungsten-containing barrier layer over the high-k dielectric layer comprises depositing tungsten carbide over the high-k dielectric layer;
depositing the first tungsten-containing work function material over the tungsten-containing barrier layer comprises depositing tungsten nitride over the tungsten-containing barrier layer; and
depositing the second tungsten-containing work function material on the first tungsten-containing work function layer comprises depositing tungsten carbide on the first tungsten-containing work function layer.

20-22. (canceled)

23. A method for fabricating an integrated circuit, the method comprising:
providing a semiconductor substrate including a pFET region and an nFET region;
depositing tungsten carbide over the pFET region and the nFET region of the semiconductor substrate to form a first metal layer;
depositing tungsten carbide or tungsten carbide nitride on to the first metal layer over the pFET region and the nFET region of the semiconductor substrate to form a second metal layer;
selectively doping the second metal layer over a selected region with aluminum to define a modified second metal layer having a first work function value over the selected region and a non-modified second metal layer having a second work function value over a non-selected region, wherein the first work function is different from the second work function value; and
depositing a tungsten metal fill over the modified second metal layer and over the non-modified second metal layer.

24. The method of claim 23 further comprising depositing tungsten carbide on to the second metal layer over the pFET region and the nFET region of the semiconductor substrate to form a third metal layer.

25. The method of claim 23 wherein depositing tungsten carbide over the pFET region and the nFET region of the semiconductor substrate forms the first metal layer with a thickness of from about 8 Å to about 15 Å.
